(19) United States
(12) Patent Application Publication
(10) Pub. No.: US 2012/0223315 A1
(43) Pub. Date: Sep. 6, 2012

(54) DISPLAY DEVICE AND MANUFACTURING METHOD OF THE SAME

(75) Inventors: Norihiro UEMURA, Mobara (JP); Hidekazu MIYAKE, Mobara (JP); Isao SUZUMURA, Tokyo (JP); Takeshi KURIYAGAWA, Mobara (JP)

(73) Assignee: Hitachi Displays, Ltd.

(21) Appl. No.: 13/406,548

(22) Filed: Feb. 28, 2012

(30) Foreign Application Priority Data
Mar. 2, 2011 (JP) 2011-045448

(51) Int. Cl. H01L 29/786; H01L 33/08

(52) U.S. Cl. 257/72; 438/34; 257/E33.055; 257/E29.273

(57) ABSTRACT

Disclosed is a display device including: a gate electrode; a semiconductor layer formed into an island shape on an upper side of the gate electrode; a side wall oxide film formed on a lateral surface of the semiconductor layer; and a drain electrode and a source electrode formed on an upper side of the semiconductor layer extending from a lateral side of the semiconductor layer, wherein the side wall oxide film has a thickness of 2.1 nm or more.

### CROSS-REFERENCE TO RELATED APPLICATION

The present application claims priority from Japanese application JP2011-045448 filed on Mar. 2, 2011, the content of which is hereby incorporated by reference into this application.

### BACKGROUND OF THE INVENTION

1. Field of the Invention

The present invention relates to a display device and a manufacturing method of a display device.

2. Description of the Related Art

In a display device such as a liquid crystal display device or an organic EL display device, a thin-film transistor (TFT) having an inverted staggered structure is sometimes used.

Further, JP 2006-243344 A discloses a manufacturing method of a liquid crystal display device which causes little leak in a manufactured thin-film transistor and has a large process margin, and also discloses that the method includes forming a side wall oxide film on an outer peripheral side wall of a laminate including an operating semiconductor layer and a low-resistance semiconductor layer using ozone water.

### SUMMARY OF THE INVENTION

However, due to oxidation by ozone water or high-pressure oxidation, even if a side wall oxide film is formed, an Off-state current caused by a leakage current cannot be sufficiently suppressed in some cases.

In view of the above problem, an object of the invention is to provide a display device having a side wall oxide film capable of suppressing an Off-state current. Further, another object of the invention is to provide a manufacturing method of a display device having a side wall oxide film capable of suppressing an Off-state current.

In order to achieve the above objects, a display device according to an aspect of the invention includes: a gate electrode; a semiconductor layer formed into an island shape on an upper side of the gate electrode; a side wall oxide film formed on a lateral surface of the semiconductor layer; and a drain electrode and a source electrode formed on an upper side of the semiconductor layer extending from a lateral side of the semiconductor layer, wherein the side wall oxide film has a thickness of 2.1 nm or more.

Further, the display device according to the aspect of the invention may be configured such that a boundary between the side wall oxide film and the semiconductor layer is formed substantially linearly from the lower surface to the upper surface of the semiconductor layer.

Further, the display device according to the aspect of the invention may be configured such that the semiconductor layer includes an ohmic contact layer, and the ohmic contact layer is formed on an upper surface of the semiconductor layer and is in contact with either of the drain electrode and the source electrode.

Further, the display device according to the aspect of the invention may be configured such that the semiconductor layer includes a microcrystalline layer, and the side wall oxide film is formed on a lateral surface of the microcrystalline layer.

Further, the display device according to the aspect of the invention may be configured such that the semiconductor layer is formed with a taper, and the side wall oxide film is formed slanting along the taper of the semiconductor layer.

Further, the display device according to the aspect of the invention may be configured such that an etching rate when the side wall oxide film is etched with a buffered hydrofluoric acid solution diluted with water to 100 times is 2.0 nm/min or lower.

Further, in order to achieve the above object, a manufacturing method of a display device according to an aspect of the invention is a manufacturing method of a display device having a plurality of thin-film transistors, and includes: a step of forming a semiconductor layer; a step of forming a resist having a thickness of 4.0 μm or more on the semiconductor layer; a step of processing the semiconductor layer into an island shape by etching using the resist as a mask; and an ashing step of forming a side wall oxide film on a lateral surface of the semiconductor layer by oxygen ashing at a temperature of 250° C. or higher in a state where the resist is left on the semiconductor layer processed into an island shape.

Further, the manufacturing method of a display device according to the aspect of the invention may be configured such that the semiconductor layer includes a microcrystalline layer, and in the asking step, the side wall oxide film is formed on a lateral surface of the microcrystalline layer.

Further, the manufacturing method of a display device according to the aspect of the invention may be configured such that the semiconductor layer is formed with a taper, and the side wall oxide film is formed slanting along the taper of the semiconductor layer.

According to the invention, a display device having a side wall oxide film capable of suppressing an Off-state current can be provided. Further, according to the invention, a manufacturing method of a display device having a side wall oxide film capable of suppressing an Off-state current can be provided.

### BRIEF DESCRIPTION OF THE DRAWINGS

FIG. 1 is a view showing an equivalent circuit on a thin-film transistor substrate of a display device according to a first embodiment of the invention.

FIG. 2 is an enlarged plan view showing a pixel region of the thin-film transistor substrate in the first embodiment.

FIG. 3 is a view showing a cross section taken along the line III-III in FIG. 2.

FIG. 4 is a view illustrating a process for forming a thin-film transistor of the display device of the first embodiment.

FIG. 5A is a view showing a mode of manufacturing the thin-film transistor of the first embodiment.

FIG. 5B is a view showing a mode of manufacturing the thin-film transistor of the first embodiment.

FIG. 5C is a view showing a mode of manufacturing the thin-film transistor of the first embodiment.

FIG. 5D is a view showing a mode of manufacturing the thin-film transistor of the first embodiment.

FIG. 5E is a view showing a mode of manufacturing the thin-film transistor of the first embodiment.

FIG. 5F is a view showing a mode of manufacturing the thin-film transistor of the first embodiment.

FIG. 5G is a view showing a mode of manufacturing the thin-film transistor of the first embodiment.

FIG. 6 is a view showing a cross section of a thin-film transistor in a modification example of the first embodiment.

FIG. 7A is a graph showing a relationship between an ashing time and a film thickness of a side wall oxide film formed in the first embodiment and a relationship between an ashing time and an etching rate when etching the side wall oxide film.

FIG. 7B is a conceptual view showing a relationship between a film thickness of the side wall oxide film and an Off-state current of the thin-film transistor.

FIG. 7C is a view showing a dependency of an On-state current and an Off-state current on an ashing time.

### DETAILED DESCRIPTION OF THE INVENTION

Hereinafter, embodiments of the invention will be described with reference to the accompanying drawings.

The display device according to a first embodiment of the invention is an in-plane switching (IPS) mode liquid crystal display device, and is configured to include a thin-film transistor substrate on which scanning signal lines, video signal lines, thin-film transistors, pixel electrodes, and counter electrodes are formed, a counter substrate which faces the thin-film transistor substrate and is provided with a color filter, and a liquid crystal material which is enclosed in a region sandwiched between the thin-film transistor substrate and the counter substrate.

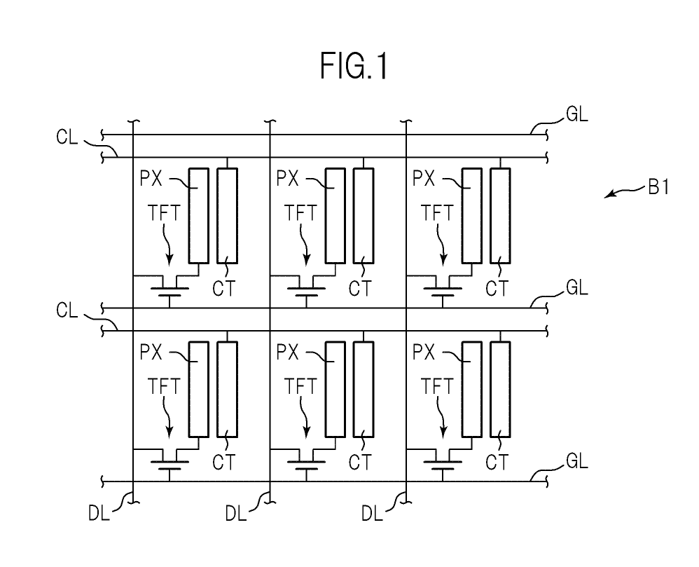

FIG. 1 is a view showing an equivalent circuit on a thin-film transistor substrate B1 of the liquid crystal display device according to the first embodiment. As shown in FIG. 1, in the thin-film transistor substrate B1, a large number of scanning signal lines GL extend in the horizontal direction in the drawing at equal intervals, and also a large number of video signal lines DL extend in the vertical direction in the drawing at equal intervals. Pixel regions arranged in a matrix array are defined by the scanning signal lines GL and the video signal lines DL, respectively. Further, common signal lines CL extend in the horizontal direction in the drawing parallel to the respective scanning signal lines GL.

FIG. 2 is an enlarged plan view showing one pixel region in the thin-film transistor substrate B1. As shown in FIG. 2, at a corner of the pixel region defined by the scanning signal lines GL and the video signal lines DL, a thin-film transistor having a metal-insulator-semiconductor (MIS) structure is formed, and a gate electrode GT of the thin-film transistor is connected to the scanning signal line GL, and a drain electrode DT of the thin-film transistor is connected to the video signal line DL. In each pixel region, a pair of a pixel electrode PX and a counter electrode CT is formed, and the pixel electrode PX is connected to a source electrode ST of the thin-film transistor, and the counter electrode CT is connected to the common signal line CL.

In the above-mentioned structure, a reference voltage is applied to the counter electrodes CT of the respective pixels via the common signal lines CL and a gate voltage is applied to the scanning signal lines GL so as to select a row of pixels. Further, at such selection timing, a video signal is supplied to the respective video signal lines DL so that a voltage of the video signal is applied to the pixel electrodes PX of the respective pixels. By such an operation, a lateral electric field having a field strength corresponding to a potential difference between the pixel electrode PX and the counter electrode CT is generated, and the orientation of liquid crystal molecules is determined according to the field strength of the lateral electric field.

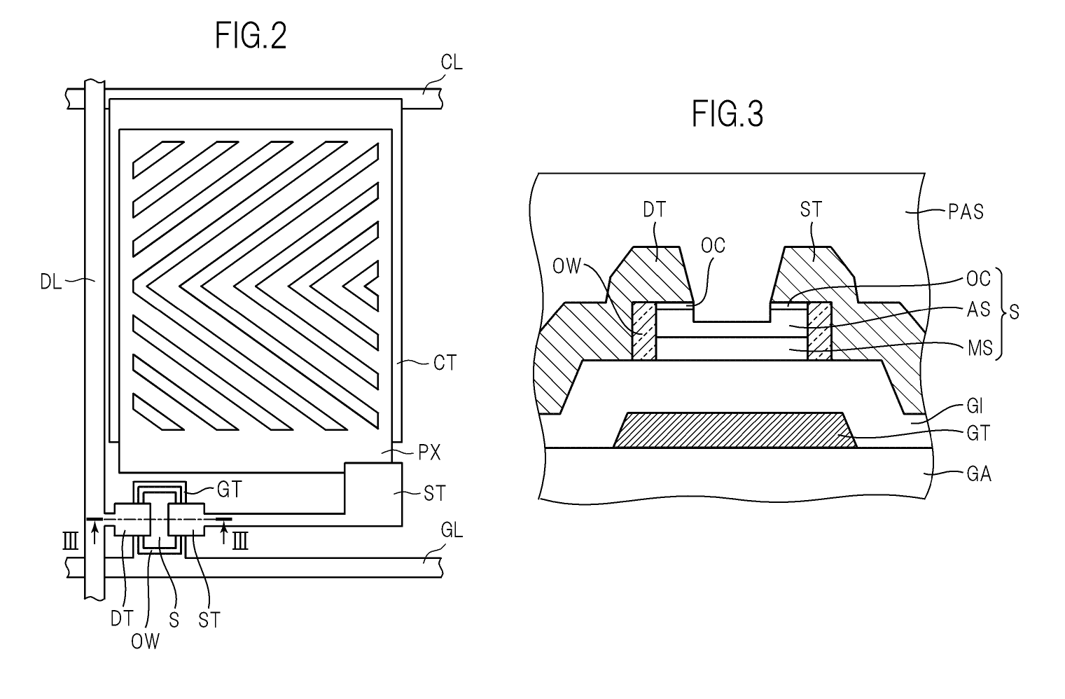

Subsequently, the thin-film transistor of this embodiment will be described in detail. FIG. 3 is a view showing a cross section taken along the line in FIG. 2. As shown in FIG. 3, in the thin-film transistor according to this embodiment, a semiconductor layer S is formed on an upper side of the gate electrode GT via a gate insulating film GI. The semiconductor layer S has a channel layer for controlling a current between the drain electrode DT and the source electrode ST according to a voltage applied to the gate electrode GT. Meanwhile, a side wall oxide film OW is formed on a lateral surface of the semiconductor layer S. Further, the drain electrode DT and the source electrode ST are formed on an upper side of the semiconductor layer S extending from a lateral side of the semiconductor layer S. In this embodiment, the drain electrode DT and the source electrode ST are formed such that on a lateral side of the semiconductor layer S, the lower surfaces thereof are in contact with the gate insulating film GI, respectively. Further, the drain electrode DT and the source electrode ST are formed such that the electrodes overlap the semiconductor layer S and are in contact with the upper surface of the semiconductor layer S, respectively.

The semiconductor layer S of this embodiment is configured to include a laminate of a microcrystalline layer MS and an amorphous layer AS, and also include an ohmic contact layer OC. The ohmic contact layer OC is formed in two places on the upper surface of the semiconductor layer S and one is in contact with the source electrode ST and the other is in contact with the drain electrode DT.

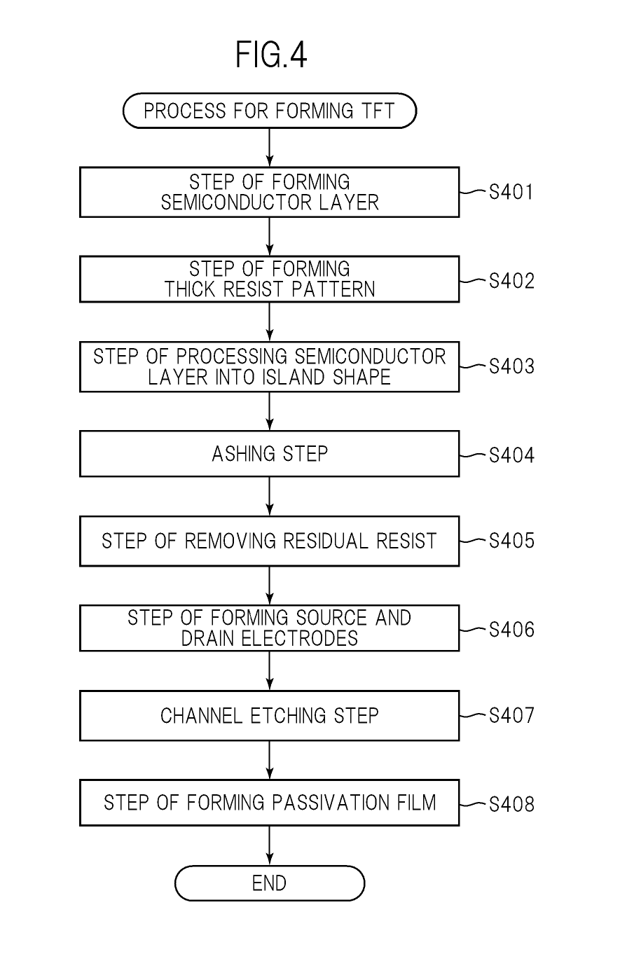

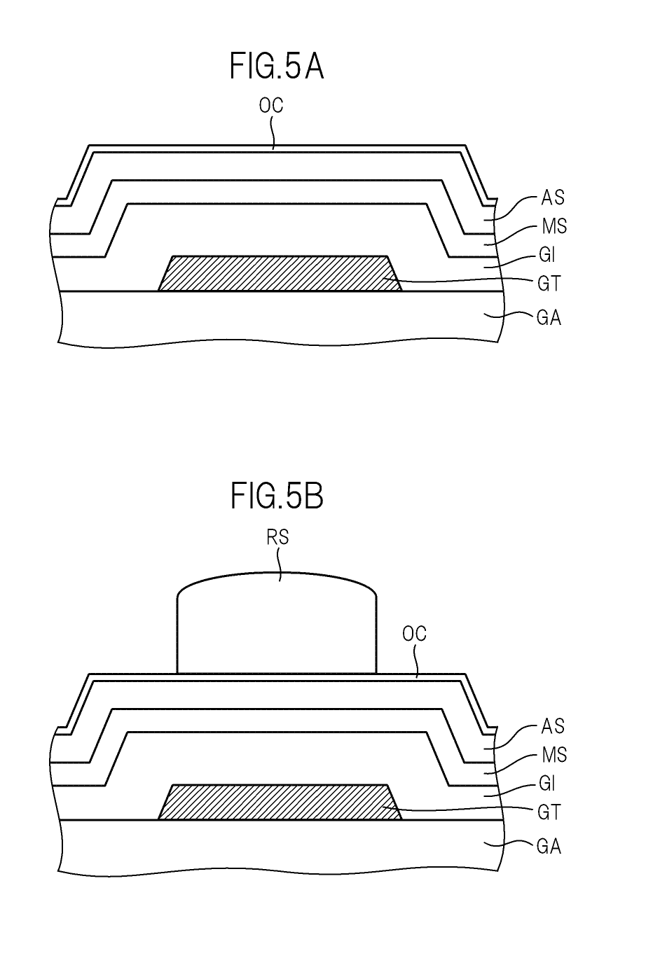

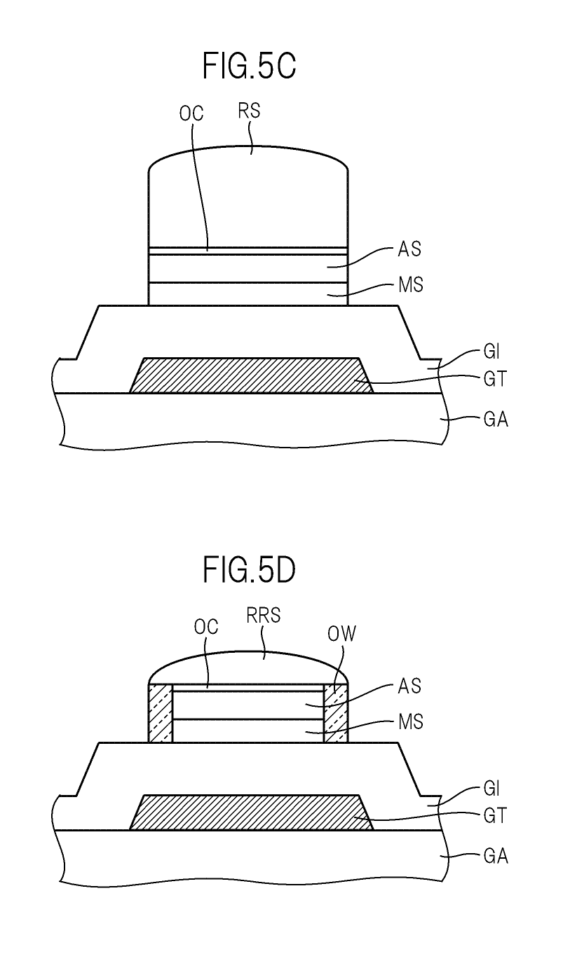

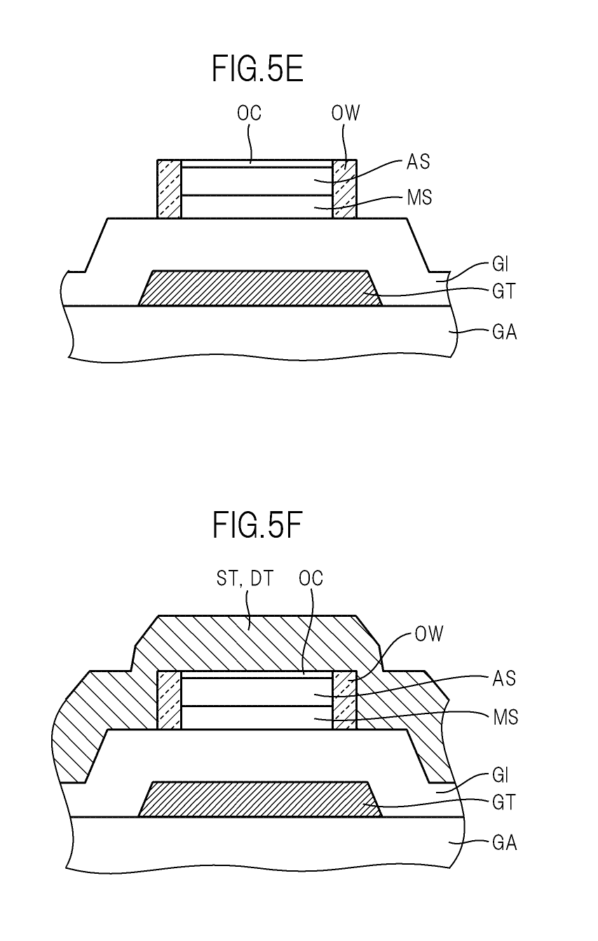

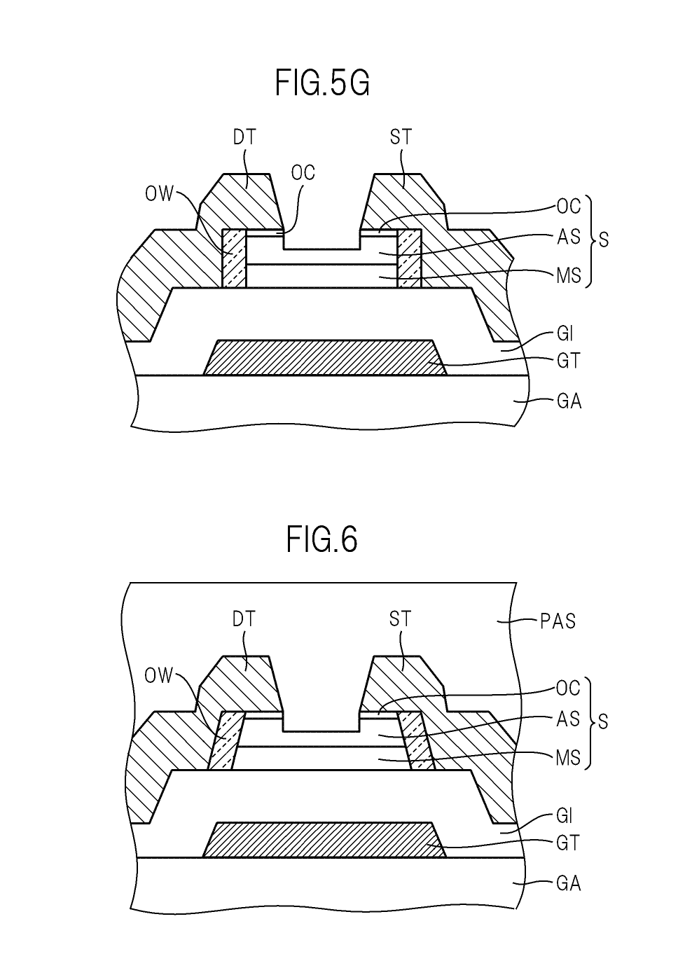

Subsequently, the side wall oxide film OW is formed on the outer periphery of the semiconductor layer S formed into an island shape in a plan view as shown in FIG. 2. Although a detailed description will be given later, the side wall oxide film OW is formed by performing oxygen asking at a temperature of 250° C. or higher in a state where a resist for use in processing the semiconductor layer S is formed thicker than that in the related art. Therefore, the side wall oxide film OW is formed to have a thickness of 2.1 nm or more, which is thicker than that in the related art, and has a good film quality. Herewith an Off-state current caused by a leakage current from the side wall of the semiconductor layer S can be suppressed. Further, in this specification, the film thickness of the side wall oxide film OW is a value measured using a spectroscopic ellipsometer. The structure of the thin-film transistor according to this embodiment has been described above. Subsequently, the manufacturing method of a thin-film transistor according to this embodiment will be described with reference to FIG. 4 and FIGS. 5A to 5G.

FIG. 4 is a flow diagram showing a process for forming the thin-film transistor of this embodiment, and FIGS. 5A to 5G are views each showing a mode of manufacturing the thin-film transistor of this embodiment respectively.

First, as shown in FIG. 5A, on a substrate on which a gate electrode GT and a gate insulating film GI are formed, a semiconductor layer S (a microcrystalline layer MS, an amorphous layer AS, and an ohmic contact layer OC) is formed (S401).

The gate electrode GT is formed by, for example, depositing a conductive metal such as molybdenum and processing into a predetermined shape by lithography. Further, the gate insulating film GI is formed by depositing, for example, silicon dioxide by a CVD method. The microcrystalline layer MS is formed by depositing microcrystalline silicon directly on the gate insulating film GI by a plasma CVD method. The amorphous layer AS is also formed by depositing amorphous silicon on the microcrystalline layer MS by a plasma CVD method. Further, the ohmic contact layer OC is formed by depositing amorphous silicon doped with an impurity.

Subsequently to the step S401, as shown in FIG. 5B, a thick resist pattern RS is formed on the semiconductor layer S by lithography (S402). Thereafter, as shown in FIG. 5C, the semiconductor layer S is etched using the resist pattern RS as a mask, whereby the semiconductor layer S is processed into an island shape (S403). Then, by oxygen ashing, the side wall oxide film OW is formed (S404, FIG. 5D).

Here, in particular, in the etching when the semiconductor layer S is processed into an island shape, it has sufficed that the thickness of the resist pattern RS is about 1.5 μm, however, in this embodiment, the thickness of the resist pattern RS to be formed in S402 is set to 4.0 μm or more and 4.5 μm or less, which is nearly three times as thick as that in the related art. By forming such a thick resist, the resist pattern RS is prevented from receding toward the inner side of the semiconductor layer S in a plan view during oxygen ashing, and it becomes possible to perform ashing at a high temperature of 250 to 260° C. for a long period of time. Accordingly, in this embodiment, the side wall oxide film OW having a thickness of 2.4 nm and also having a good film quality is formed along a lateral surface of the semiconductor layer S.

Subsequently, after completion of the ashing step S404, the resulting product is in a state as shown in FIG. 5D, and therefore, a step of washing and removing a residual resist RRS is performed (S405, FIG. 5E). After removing the residual resist RRS, a step of forming a source electrode ST and a drain electrode DT on an upper side of the semiconductor layer S is performed (S406). In S406, first, as shown in FIG. 5F, a film of a metal material such as aluminum is formed by sputtering and is processed into the shape of an electrode by photolithography. After the film is processed into the shape of a source electrode ST or the like, the semiconductor layer S is subjected to channel etching as shown in FIG. 5G (S407), and then, a passivation film PAS is formed on the entire upper surface of the thin-film transistor (S408).

The process for forming the thin-film transistor of this embodiment has been described above. As described above, the resist pattern RS is formed to have a thickness of 4.0 μm or more. Therefore, even if oxygen ashing is performed at a high temperature of 250° C. or higher in S404, the resist pattern RS is prevented from receding and oxidation of the semiconductor layer S from the upper surface side is prevented. Further, on the lower side of the source electrode ST and the drain electrode DT, a boundary between the side wall oxide film OW and the semiconductor layer S is formed linearly from the lower surface to the upper surface of the semiconductor layer S as shown in FIG. 3 or the like. In other words, the side wall oxide film OW is formed such that the width (thickness seen from the lateral side) of the side wall oxide film OW is substantially equal from the upper surface to the lower surface. Here, if the resist pattern RS recedes during ashing, an outer peripheral portion of an upper surface of the semiconductor layer S is oxidized, and the side wall oxide film OW is formed such that the width thereof on the upper surface is thicker than that on the lower surface. Due to this, in the case where an ohmic contact layer OC is formed on an upper surface of the semiconductor layer S, there is a possibility that in a portion where the side wall oxide film OW is not present, even if the ohmic contact layer OC is completely etched, etching of the ohmic contact layer OC is inhibited in an outer peripheral portion where the side wall oxide film OW has been formed, and a leakage path may be formed along the outer periphery of the semiconductor layer S.

Accordingly, in the case where an ohmic contact layer OC is formed as in the case of this embodiment, by forming the side wall oxide film OW as described above (S402 to S404), the formation of a leakage path is prevented, thereby preventing an Off-state current from generating.

FIG. 6 is a cross-sectional view of a thin-film transistor according to a modification example of this embodiment, and shows a cross section at a position corresponding to the cross section taken along the line III-III in FIG. 2. As shown in FIG. 6, the semiconductor layer S of the thin-film transistor according to this modification example is formed with a taper angle, and also the side wall oxide film OW is formed along a lateral surface of the semiconductor layer S.

In the step of processing the semiconductor layer S into an island shape (S403) in this modification example, the semiconductor layer S is subjected to side etching toward the inner side of the thick resist pattern RS. Therefore, this modification example is preferred in terms of the following point. In the asking step S404, the upper surface of the semiconductor layer S is in contact with an inner side surface of the resist pattern RS. As a result, it becomes more difficult to oxidize the upper surface of the semiconductor layer S, and it becomes easier to oxidize the lateral surface of the semiconductor layer S by forming the semiconductor layer S having a taper.

Subsequently, a comparative example will be described. In this comparative example, a display device is manufactured in substantially the same manner as in the first embodiment except that in S402, the thickness of the resist pattern RS is changed to about 1.5 μm, and in the asking step S404, a lateral surface of the semiconductor layer S is oxidized using high-temperature pure water.

Table 1 shows the film thickness of the side wall oxide film OW, the etching rate thereof, and an Off-state current of the thin-film transistor in the above-described first embodiment and comparative example.

TABLE 1

| | Comparative | First |
|---|---|---|
| | example | embodiment |
| Film thickness of side wall oxide film (nm) | 1.4 | 2.4 |
| Etching rate (nm/min) | 3.4 | 1.5 |
| Off-state current (pA/μm) | 10 | 0.9 |

The Off-state current in Table 1 is a drain current value when the drain voltage is set to 10 V and the gate voltage is set to −10 V. As is apparent from Table 1, the Off-state current in the first embodiment is about one-tenth of that in the comparative example. Further, the etching rate in Table 1 is an etching rate when etching is performed using a buffered hydrofluoric acid solution and is used as an index for representing the film quality of the side wall oxide film OW. As the etching rate is decreased, the film density of the side wall oxide film OW is increased, and therefore the film quality is improved.

As shown by the results of Table 1, in the case of the side wall oxide film OW according to the first embodiment, the film thickness of the side wall oxide film OW is larger and also the film quality thereof is favorable as compared with the case of the side wall oxide film OW formed in the comparative example. By forming the side wall oxide film OW through oxygen ashing at a high temperature of 250° C. or higher as in the case of the first embodiment, oxidation can be achieved from a lateral side of the semiconductor layer S to a deep position thereof, and also the density of the oxygen atoms in an oxide film can be increased as compared with the case of the comparative example. Further, by forming the resist pattern RS to have a thickness of 4.0 μm or more, the resist is prevented from receding even if ashing is performed at a high temperature of 250° C. or higher, and an adverse effect of oxidation of the upper surface of the semiconductor layer S can be avoided. As described above, the thickness and film quality of the side wall oxide film OW can be improved by a simpler process than in the case of the comparative example. Further, in the above-described ashing step, by releasing the TFT substrate in a state where the resist is sufficiently left thereon into the atmosphere once, and thereafter subjecting the TFT substrate to ashing again, the film quality of the oxide film can be further improved.

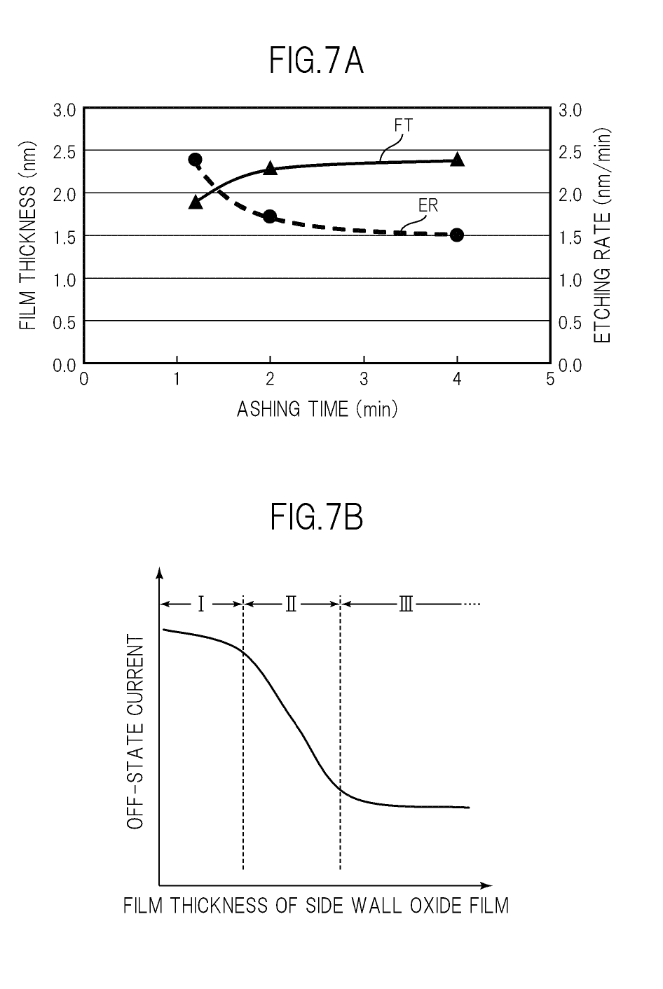

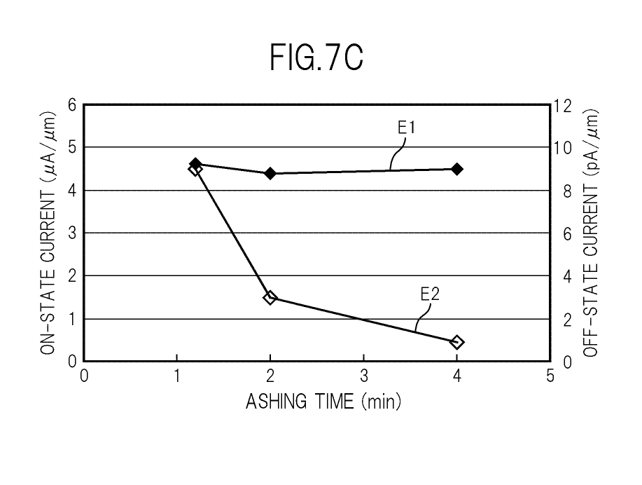

FIG. 7A is a graph showing a relationship between an ashing time and a film thickness of the side wall oxide film OW formed in the first embodiment (FT) and a relationship between an ashing time and an etching rate when etching the side wall oxide film OW formed in the first embodiment (ER). In FIG. 7A, the relationship between an ashing time and a film thickness of the side wall oxide film OW is indicated by a solid line, and the relationship between an ashing time and an etching rate of the side wall oxide film OW is indicated by a dashed line. Further, the etching rate as used herein refers to a dissolution rate when the side wall oxide film OW formed in the ashing step S404 is etched with a buffered hydrofluoric acid solution diluted with water to 100 times and indicates the film quality of the oxide film.

As shown in FIG. 7A, when oxygen ashing is performed for 2 minutes, the film thickness of the side wall oxide film OW is increased to 2.3 nm, and when ashing is further continued, an increase in the film thickness with respect to the ashing time becomes gradual, and the film thickness of the side wall oxide film OW becomes 2.4 nm when ashing is performed for 4 minutes. The side wall oxide film OW is preferably formed to have a thickness of 2.1 nm or more by performing oxygen ashing for 1.5 minutes or more. Further, in the case where oxygen ashing is performed for 1.5 minutes, the etching rate becomes 2.0 nm/min as shown in FIG. 7A.

In the first embodiment, if oxygen ashing in S404 is performed at a temperature of 100° C. or lower, the etching rate becomes about 3 nm/min, and therefore, the film quality cannot be improved under such a temperature condition.

FIG. 7B is a conceptual view showing a relationship between a film thickness of the side wall oxide film OW and an Off-state current of the thin-film transistor. The magnitude of the Off-state current is divided into three regions based on the film thickness of the side wall oxide film OW. A region I is a range of the film thickness in which the film thickness of the oxide film is thin and an effect of decreasing the Off-state current is low; a region II is a range in which as the film thickness of the oxide film is increased, the Off-state current is decreased; and a region III is a range of the film thickness in which even if the film thickness of the oxide film is increased, the Off-state current is not decreased.

When the side wall oxide film OW is formed to be thin (in a range of the region I), the film quality is poor in most cases and an effect of decreasing the Off-state current is hardly exhibited. Further, in the case where the thickness of the oxide film falls within the region II, in the vicinity of the boundary of the oxide film, an electron state is such that electrons penetrate from the semiconductor layer S (silicon layer) to the side wall oxide film OW (silicon dioxide layer) by about 0.1 to 0.2 nm, and if the film thickness of the side wall oxide film OW is thin, electrons are accelerated by the electric field and a current flows. As a result, a leakage current is generated. Meanwhile, if the film thickness of the side wall oxide film OW is increased, a potential barrier against the current becomes large, resulting in decreasing the leakage current. In the region III, the film thickness is sufficient, and therefore, the leakage current from the side wall is almost prevented.

FIG. 7C is a view showing a dependency of an On-state current and an Off-state current on an ashing time, and shows an On-state current and an Off-state current of the thin-film transistor according to the first embodiment. The On-state current is a drain current value when the drain voltage is set to 10 V and the gate voltage is set to 10 V, and the Off-state current is a drain current value when the drain voltage is set to 10 V and the gate voltage is set to −10 V, each of which is a value per unit channel width. As shown in FIG. 7C, the On-state current (E1) does not so much depend on the ashing time, and the Off-state current (E2) begins to decrease after the ashing time exceeds 1 minute, and becomes 3 pA/μm or less when the ashing time is 2 minutes.

In the step S405 in which the residual resist RRS is washed and removed, a thin oxide film in which the density of the oxygen atoms is low can be formed on the upper surface of the semiconductor layer S, however, even if such an oxide film is formed, electrical connection between the semiconductor layer S and the source electrode ST or the like is not inhibited.

The display device according to this embodiment is an IPS mode liquid crystal display device, however, the display device may be a liquid crystal display device adopting another driving mode such as a vertically aligned (VA) mode or a twisted nematic (TN) mode, or may be another display device such as an organic EL display device.

Although the respective embodiments of the invention have been described above, the invention is not limited to the above-described embodiments and various modifications can be made. For example, the configurations described in the embodiments can be replaced by substantially the same configuration, a configuration providing the same action and effect, or a configuration which can achieve the same object.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a gate electrode;
a semiconductor layer formed into an island shape on an upper side of the gate electrode;
a side wall oxide film formed on a lateral surface of the semiconductor layer; and
a drain electrode and a source electrode formed on an upper side of the semiconductor layer extending from a lateral side of the semiconductor layer, wherein
the side wall oxide film has a thickness of 2.1 nm or more.

2. The display device according to claim 1, wherein
a boundary between the side wall oxide film and the semiconductor layer is formed substantially linearly from a lower surface to an upper surface of the semiconductor layer.

3. The display device according to claim 2, wherein
the semiconductor layer includes an ohmic contact layer; and
the ohmic contact layer is formed on an upper surface of the semiconductor layer and is in contact with either of the drain electrode and the source electrode.

4. The display device according to claim 1, wherein
the semiconductor layer includes a microcrystalline layer; and
the side wall oxide film is formed on a lateral surface of the microcrystalline layer.

5. The display device according to claim 1, wherein
the semiconductor layer is formed with a taper; and
the side wall oxide film is formed slanting along the taper of the semiconductor layer.

6. The display device according to claim 1, wherein
an etching rate when the side wall oxide film is etched with a buffered hydrofluoric acid solution diluted with water to 100 times is 2.0 nm/min or lower.

7. A manufacturing method of a display device having a plurality of thin-film transistors, comprising:
a step of forming a semiconductor layer;
a step of forming a resist having a thickness of 4.0 μm or more on the semiconductor layer;
a step of processing the semiconductor layer into an island shape by etching using the resist as a mask; and
an ashing step of forming a side wall oxide film on a lateral surface of the semiconductor layer by oxygen ashing at a temperature of 250° C. or higher in a state where the resist is left on the semiconductor layer processed into an island shape.

8. The manufacturing method of a display device according to claim 7, wherein
the semiconductor layer includes a microcrystalline layer; and in the asking step, the side wall oxide film is formed on a lateral surface of the microcrystalline layer.

9. The manufacturing method of a display device according to claim 7, wherein
the semiconductor layer is formed with a taper; and
the side wall oxide film is formed slanting along the taper of the semiconductor layer.
